(19) United States
(12) Patent Application Publication
(10) Pub. No.: US 2004/0191999 A1
(43) Pub. Date: Sep. 30, 2004

(54) Semiconductor structure and method of fabrication

(75) Inventors: Pr Chidambaram, Richardson, TX (US); Srinivasan Chakravarthi, Richardson, TX (US); Gautam V. Thakar, Plano, TX (US); Toan Tran, Rowlett, TX (US)

Correspondence Address: TEXAS INSTRUMENTS INCORPORATED, P O BOX 655474, M/S 3999, DALLAS, TX, 75265

(73) Assignee: Texas Instruments Incroporated

(21) Appl. No.: 10/396,139

(22) Filed: Mar. 24, 2003

(51) Int. Cl. H01L 21/336

(52) U.S. Cl. 438/305

(57) ABSTRACT

Fabricating a semiconductor includes forming a conductive layer outwardly from a surface of a substrate. A mask layer comprising a hard mask is deposited outwardly from the conductive layer to pattern the conductive layer to form a gate stack. The conductive layer is etched to remove the conductive layer from the surface of the substrate and to form the gate stack, where the mask layer is disposed outwardly from the gate stack. Ions are implanted outwardly from the surface of the substrate, where the mask layer prevents at least a portion of the ions from penetrating the gate stack while penetrating the substrate.

### TECHNICAL FIELD OF THE INVENTION

This invention relates generally to the field of integrated circuit fabrication and specifically to a semiconductor structure and method of fabrication.

### BACKGROUND OF THE INVENTION

Transistors are generally fabricated by doping a masked substrate to form a source and a drain. The dopants may be implanted in the substrate to reduce source-drain diffusion. The dopants, however, may diffuse farther into the substrate than required, resulting in undesirable consequences. Adding ion implants such as fluorine at the doping stage is a technique that may assist in reducing diffusion of the dopants. The addition of these ions, however, may increase the apparent oxide thickness, or tox inversion, if the fluorine ions penetrate the gate stack. Tox inversion reduces performance of the integrated circuit by reducing the capacitance that the gate stack may contribute to the transistor circuit and the device current. Consequently, known techniques for ion implantation are unsatisfactory in certain situations.

### SUMMARY OF THE INVENTION

In accordance with the present invention, disadvantages and problems associated with previous techniques for fabricating a semiconductor structure may be reduced or eliminated.

According to one embodiment, a method of fabricating a semiconductor includes forming a conductive layer outwardly from a surface of a substrate. A mask layer comprising a hard mask is disposed outwardly from the conductive layer to pattern the conductive layer to form a gate stack. The conductive layer is etched to remove the conductive layer from the surface of the substrate and to form the gate stack, where the mask layer is disposed outwardly from the gate stack. A plurality of ions are implanted outwardly from the surface of the substrate, where the mask layer is operable to prevent at least a portion of the ions from penetrating the gate stack while penetrating the substrate.

Certain embodiments of the invention may provide one or more technical advantages. A technical advantage of one embodiment of the present invention may include a mask layer that may reduce or prevent ion penetration of a gate stack. The low ion penetration may result in improved performance by maintaining the capacitance contributed by the gate stack to the transistor circuit.

Certain embodiments of the invention may include none, some, or all of the above technical advantages. One or more other technical advantages may be readily apparent to one skilled in the art from the figures, descriptions, and claims included herein.

### BRIEF DESCRIPTION OF THE DRAWINGS

For a more complete understanding of the present invention and its features and advantages, reference is now made to the following description, taken in conjunction with the accompanying drawings, in which:

FIGS. 1A-1E are a series of schematic cross-sectional diagrams illustrating an embodiment of a method for fabricating a transistor in accordance with the present invention; and

FIG. 2 is a graph illustrating a profile of concentration of fluorine in the hard mask in accordance with one embodiment of the present invention.

### DETAILED DESCRIPTION OF THE DRAWINGS

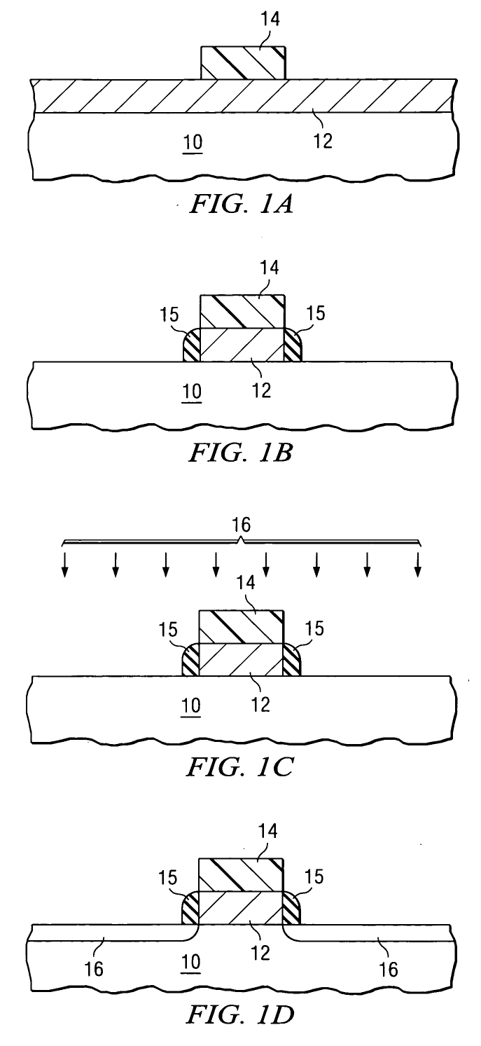

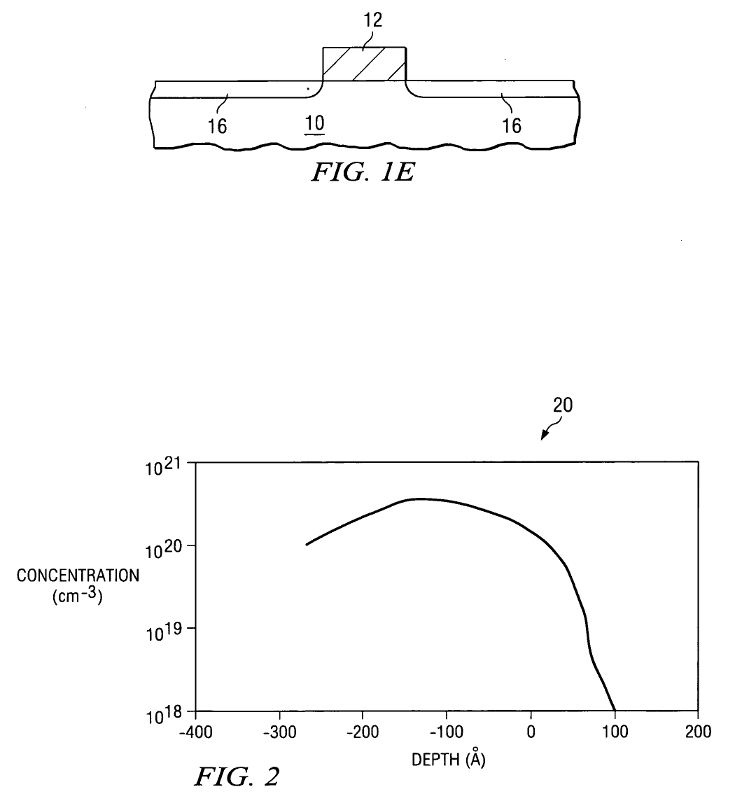

Embodiments of the present invention and its advantages are best understood by referring to FIGS. 1 and 2 of the drawings, like numerals being used for like and corresponding parts of the various drawings.

FIGS. 1A-1E are a series of schematic cross-sectional diagrams illustrating an embodiment of a method for fabricating a transistor in accordance with the present invention. The method illustrated in FIGS. 1A-1E may be used with either positive metal oxide semiconductor (PMOS) or negative metal oxide semiconductor (NMOS) devices.

Referring to FIG. 1A, a substrate 10 may comprise a silicone substrate or silicone epitaxial layer. Other suitable substrates, however, may alternatively be used. A conductive layer 12 is disposed outwardly from substrate 10, and may be formed according to any conventional method of fabrication of semiconductors. Conductive layer 12 may comprise any suitable conductive material, and may have any thickness desired according to the application. For example, conductive layer 12 may have any thickness in a range between 80 and 2200 nanometers. According to the illustrated embodiment, conductive layer 12 comprises a polysilicon layer of a thickness of approximately 1200 nanometers.

A mask layer 14 is deposited outwardly from the conductive layer 12 by applying photoresist material to form a pattern. Mask layer 14 may be formed into any pattern according to the specific application. For example, mask layer 14 may be formed into a gate stack pattern. According to one embodiment, forming a pattern may comprise a patterning process, such as lithography, masking, photolithography, photomasking, microlithography, or any other suitable technique for transferring a pattern onto a surface layer of a substrate 10.

Mask layer 14 may have any thickness suitable for patterning and etching conductive layer 12. The thickness of mask layer 14 may be sufficient to enable mask layer 14 to be etched while protecting conductive layer 12 as will be described with reference to FIG. 1C. According to the illustrated embodiment, mask layer 14 comprises a double layered hard mask of a thickness in a range between 300 and 500 Angstroms.

Referring to FIG. 1B, conductive layer 12 is etched to remove portions of conductive layer 12 not protected by mask layer 14. The etching process may also reduce the thickness of mask layer 14 resulting in a mask layer thickness of at least approximately 250 Angstroms. According to the illustrated embodiment, a passivating layer 15 may be formed outwardly from the sides of the formed gate stack. The passivating layer 15 may be formed from an oxide layer that is grown on the surface due to exposure of the substrate to air or otherwise.

Referring to FIG. 1C, an ion beam 16 is directed towards substrate 10 for ion implantation. Ion beam 16 may comprise any suitable ions, such as fluorine ions, nitrogen ions, or carbon ions. The ions may be accelerated at an energy level in the range between 0.5 keV and 25 keV, and may be implanted using a dosage in the range between E13 and E15 atoms/cm². According to the illustrated embodiment, a fluorine implant is formed using an E15 dosage and an acceleration of 8 keV. In a particular embodiment, F+ ions are implanted to reduce the effect of diffusion of dopants in source drain (SD) and mildly doped drain (MDD) applications.

Mask layer 14 is operable to obstruct at least a portion of the ions from penetrating the gate stack. For example, the hard mask may have a thickness sufficient to retain approximately 98% of the ion dosage penetrating the hard mask. According to one embodiment, mask layer 14 and passivating layer 15 both protect the ions from penetrating the gate stack.

Referring to FIG. 1D, ion implant 16 is formed outwardly from substrate 10. An annealing step may be performed after ion implantation to enable the new ions to be suitably placed within the substrate crystal lattice. According to one embodiment, the annealing step may be performed by heating the substrate to a temperature between 800° C. to 1000° C. to repair any disruptions in the crystal formed by the inclusion of the ions in substrate 10.

Referring to FIG. 1E, after performing the ion implantation, mask layer 14 is stripped during a hard mask cleaning process. The hard mask cleaning process may comprise a wet chemical etch that removes the photoresist material of the hard mask, thus removing mask layer 14. Any stripping technique, however, may be used to remove mask layer 14 without departing from the scope of the invention. After stripping the mask layer 14, substrate 10 may undergo further manufacturing process stages to fabricate any transistor according to the application.

FIG. 2 is a graph 20 illustrating a concentration profile of fluorine in accordance with one embodiment of the present invention. The concentration of fluorine ions through mask layer 14 relative to the depth of the hard mask is shown in FIG. 2. The impurity concentration profile reflects the fluorine penetration through a mask layer 14 of a thickness of 250 Angstroms after ion implantation as described with reference to FIG. 1C.

In the illustrated embodiment, the concentration of fluorine ions decreases with the thickness of the hard mask. Typically, a hard mask thickness of at least 250 Angstroms is used for an ion implantation at an acceleration of 8 keV. As shown by the profile, the hard mask may retain 98% of the dosage penetrating the hard mask, therefore reducing penetration of ions in conductive layer 12. Although an example value of ion retention has been given in response to the concentration profile of fluorine, it should be understood that any appropriate values may be used in particular embodiments. For example, the thickness of the mask layer may be adjusted as the acceleration and dosages of ions vary.

Certain embodiments of the invention may provide one or more technical advantages. A technical advantage of one embodiment of the present invention may include a mask layer that may reduce or prevent ion penetration of a gate stack. The low ion penetration may result in improved performance by maintaining the capacitance contributed by the gate stack to the transistor circuit.

Although an embodiment of the invention and its advantages are described in detail, a person skilled in the art could make various alterations, additions, and omissions without departing from the spirit and scope of the present invention as defined by the appended claims.

In the claims:

1. A method of fabricating a semiconductor device, comprising:
forming a conductive layer outwardly from a surface of a substrate;
depositing a mask layer comprising a hard mask outwardly from the conductive layer and patterning and etching the mask layer on the conductive layer to form a gate stack for a PMOS device and a gate stack for a NMOS device;
etching the conductive layer to remove the conductive layer from the surface of the substrate to form the gate stacks ; and
implanting a plurality of ions into the substrate of the PMOS device and the NMOS device, the mask layer operable to prevent at least a portion of the ions from penetrating the gate stack of the PMOS device and the gate stack of the NMOS device while penetrating the substrate.

2. The method of claim 1, wherein the mask layer after the etching the conductive layer has a thickness of at least 250 Angstroms.

3. The method of claim 1, wherein the plurality of ions comprises one or more ions selected from a group consisting of a plurality of fluorine ions, a plurality of nitrogen ions, and a plurality of carbon ions.

4. The method of claim 1, further comprising removing the mask layer using wet chemical etching.

5. The method of claim 1, wherein implanting the plurality of ions further comprises accelerating the ions to an energy level in a range between 0.5 keV and 25 keV.

6. The method of claim 1, wherein the mask layer comprises a layer of silicon nitride.

7. The method of claim 1, wherein implanting the plurality of ions further comprises implanting ions at a dosage in a range between E13 and E15 atoms/cm².

8. A method of fabricating a semiconductor device, comprising:
forming a conductive layer outwardly from a surface of a substrate;
forming a hard mask layer outwardly from the surface of the conductive layer;
applying a photoresist layer outwardly from the conductive layer;
developing the photoresist layer to form a mask layer pattern;
etching the conductive layer to remove one or more portions of the conductive layer from the surface of the substrate to form a gate stack for a PMOS device and a gate stack for a NMOS device;
implanting a plurality of fluorine ions into the substrate of, the PMOS device and the NMOS device which are masked by a hard mask operable to prevent at least a portion of the fluorine ions from penetrating the gate stack of the PMOS device and the gate stack of NMOS device; and
cleaning the substrate to remove the mask layer.

9. The method of claim 8, wherein the mask layer after the etching the conductive layer [of] is at least 250 Angstroms.

10. The method of claim 8, wherein cleaning the substrate to remove the mask layer further comprises using wet chemical etching to remove the mask layer.

11. The method of claim 8, wherein implanting the plurality of fluorine ions further comprises accelerating the fluorine ions to an energy level in a range between 0.5 keV and 25 keV.

12. The method of claim 8, wherein the mask layer comprises a layer of silicon nitride.

13. The method of claim 8, wherein implanting the plurality of fluorine ions further comprises implanting the fluorine ions at a dosage in a range between E13 and E15 atoms/cm².
